(19) United States
(12) Patent Application Publication
(10) Pub. No.: US 2017/0248642 A1
(43) Pub. Date: Aug. 31, 2017

(54) NEAR-FIELD ANTENNA MEASUREMENT METHOD AND MEASUREMENT SYSTEM USING THE SAME

(71) Applicant: National Chung Cheng University, Chia-Yi (TW)

(72) Inventors: Zuo-Min TSAI, Chia-Yi (TW); Po-Jui CHIU, Chia-Yi (TW); Dong-Chen TSAI, Chia-Yi (TW)

(21) Appl. No.: 15/164,460

(22) Filed: May 25, 2016

(30) Foreign Application Priority Data
Feb. 26, 2016 (TW) 105105870

(51) Int. Cl. G01R 29/10

(52) U.S. Cl. CPC G01R 29/10

(57) ABSTRACT

A near-field antenna measurement method and a measurement system using the same is disclosed. The measurement method chooses a measurement block to measuring an antenna signal emitted by an antenna under test on the measurement block. Firstly, a plurality of initial measurement points is chosen on measurement block and initial electric field values of the antenna signal at the initial measurement points are measured. Then, a plurality of initial interpolation points cooperating with the initial measurement points on the measurement block is chosen to comply with the sampling theorem. Interpolation is performed on the initial electric field values to obtain initial electric field interpolation values respectively corresponding to the initial interpolation points. Finally, the initial electric field values and the initial electric field interpolation values are processed to obtain electric filed convergence values of the antenna signal at the initial measurement points and the initial interpolation points.

This application claims priority for Taiwan patent application no. 105105870 filed on Feb. 26, 2016, the content of which is incorporated by reference in its entirely.

### BACKGROUND OF THE INVENTION

Field of the Invention

The present invention relates to a measurement technology, particularly to a near-field antenna measurement method and a measurement system using the same.

Description of the Related Art

In planar near-field antenna measurement, the sampling theorem is complied to avoid distorting a recovered far-field pattern of an antenna. However, if the sampling theorem is complied in measurement, many points have to be measured, which is very time-consuming.

FIG. 1 is a diagram schematically showing a planar near-field antenna measurement system in the conventional technology. The planar near-field antenna measurement system includes a scan plane 10, a receiving antenna 12 and an antenna under test 14. The planar near-field antenna measurement system moves the receiving antenna 12 to scan electric field values on the scan plane 10 provided by the antenna under test 14 one by one, and in addition to that, the receiving antenna 12 scan left to right and top to bottom. The near-field antenna measurement system measures as more electric field values on the scan plane 10 of the antenna under test as possible. Afterwards, a near-field to far-field conversion equation is used to convert the measured near-field antenna data into a far-field pattern of the antenna under test 14. The more the measured near-field antenna data is, the more precise the converted far-field pattern is. In fact, as long as the sampling theorem is complied in near-field antenna measurement, the far-field pattern of the antenna recovered by the near-field to far-field conversion algorithm is not distorted. FIG. 2 is a diagram schematically showing the sampling theorem. FIG. 2 is a measurement plane with n×n points, wherein n is a natural number. All the black points on the measurement plane denote measurement points. The sampling theorem defines that a distance between the two neighboring points is less than λ/2, wherein λ is a wavelength of an antenna signal emitted by the antenna under test 14. In other words, a distance between the two measurement points is less than λ/2, which comply with the sampling theorem in near-filed antenna measurement. As a result, the measured data is converted into a far-field pattern of the antenna, which is not distorted, by the near-field to far-field conversion algorithm. In order to comply with the sampling theorem, an electric field value is measured at an interval of λ/2 in near-field antenna measurement. Thus, many near-field data has to be measured. On the other hand, in order to improve precision of the far-field pattern of the antenna converted by the algorithm, measuring the near-field data of the antenna requires much more time.

In order to solve the time-consuming problem, the paper named fast antenna testing with reduced near field sampling uses models to produce near-field and far-field bases, and then uses the bases to compare with the measured results. In the paper, when a simple model compares with the measured results, the measurement points are reduced from 6000 to 505. When a complete model compares with the measured results, the measurement points are reduced from 6000 to 205. Thus, the method of the paper can decrease the measurement points by a scale of 99%. Nevertheless, the paper has a drawback which is that establishing a model costs a lot of time. In the paper, establishing a complete simulation model costs 15 hours, and establishing a complete basis requires 42 simulations. Although the paper using the model to measure data can save a lot of time, it is still time-consuming to consider the time of establishing simulations.

Another paper named adaptive rectangular spiral acquisition technique for planar near-field antenna measurement provides a measurement method to break through the sampling theorem. Before measurement, a whole measurement plane is divided into (n+1) ring regions m, (m+1), (m+2) . . . , (m+n) from center to outside, as shown in FIG. 3. Wherein, m and n are natural numbers. The measurement process is introduced below. Firstly, the data of the region m is the data of the main beam of an antenna under test. Then, the data of the region m and the extrapolating method are used to obtain the data of the region (m+2) taking into consideration of ignoring the data of the region (m+1). Then, the data of the region (m+2) is measured. Finally, the two data of the region (m+2) are compared. If the two data has a great difference, which means that the data obtained by the extrapolating method cannot represent the measured data, the data of the region (m+1) is measured. On the contrary, if the two data has a small difference, the data of the region (m+1) is ignored to save time. The method of the paper can decrease the measurement points by a scale of 70.7%. However, when the two data of the region (m+2) has a small difference, the data of the region (m+1) is ignored. In such a case, the recovered far-field pattern may be still inexact since the data of the region (m+1) is ignored.

To overcome the abovementioned problems, the present invention provides a near-field antenna measurement method and a measurement system using the same, so as to solve the afore-mentioned problems of the prior art.

### SUMMARY OF THE INVENTION

A primary objective of the present invention is to provide a near-field antenna measurement method and a measurement system using the same, which chooses measurement points on a measurement block to measure electric field values of an antenna under test, uses the electric field values and interpolation to obtain electric field interpolation values, and uses the electric field values and the electric field interpolation values to fast obtain precise electric field convergence values of the antenna under test, which is provided to convert a precise far-field pattern.

To achieve the abovementioned objectives, the present invention provides a near-field antenna measurement method, which chooses a measurement block corresponding to an antenna under test, such a plane, and measures an antenna signal emitted by the antenna under test. Firstly, a plurality of initial measurement points at a boundary of the measurement block is chosen and initial electric field values of the antenna signal at the initial measurement points are measured. Then, a plurality of initial interpolation points on the measurement block is chosen. A distance between each initial interpolation point and either the initial interpolation point or the initial measurement point neighboring thereto is less than a half of a wavelength of the antenna signal. Interpolation is performed on the initial electric field values to obtain initial electric field interpolation values respectively corresponding to the initial interpolation points. Finally, the initial electric field values and the initial electric field interpolation values are processed to obtain electric filed convergence values of the antenna signal at the initial measurement points and the initial interpolation points.

If the method intends to display a far-field pattern, a near-field to far-field conversion algorithm is used to convert the electric filed convergence values into a far-field pattern of the antenna under test and the far-field pattern is displayed.

The step of processing the initial electric field values and the initial electric field interpolation values to obtain the electric filed convergence values further comprises Step (a) and Step (b). In Step (a), the measurement block is divided into a plurality of n-th subblocks along paths formed by the initial measurement point and the initial interpolation point, and n is a natural number, and each n-th subblock is sequentially chosen to perform a first operation process. The first operation process comprises Step (a1), Step (a2), Step (a3) and Step (a4) sequentially performed. In Step (a1), a plurality of n-th measurement points at a boundary of the n-th subblock is chosen, and a plurality of n-th interpolation points on the n-th subblock is chosen, and positions of the n-th measurement points and the n-th interpolation points are identical to those of the initial measurement points and the initial interpolation points, and n-th electric field values of the antenna signal at the n-th measurement points are measured. In Step (a2), interpolation is performed on the n-th electric field values to obtain n-th electric field interpolation values respectively corresponding to the n-th interpolation points. In Step (a3), an initial different value is obtained according to the n-th electric field values, the n-th electric field interpolation values, the initial electric field values and the initial electric field interpolation values. In Step (a4), the first operation process determines whether the initial different value is less than a threshold value. If the answer is yes, the n-th electric field values and the n-th electric field interpolation values are used as the electric filed convergence values. If the answer is no, Step (b) is executed. In Step (b), the n-th subblock is divided into a plurality of (n+1)-th subblocks along paths formed by the n-th measurement point and the n-th interpolation point, and each (n+1)-th subblock is sequentially chosen to perform a second operation process. The second operation process comprises Step (b1), Step (b2), Step (b3) and Step (b4) sequentially performed. In Step (b1), a plurality of (n+1)-th measurement points at a boundary of the (n+1)-th subblock is chosen, and a plurality of (n+1)-th interpolation points on the (n+1)-th subblock is chosen, and positions of the (n+1)-th measurement points and the (n+1)-th interpolation points are identical to those of the n-th measurement points and the n-th interpolation points, and (n+1)-th electric field values of the antenna signal at the (n+1)-th measurement points are measured. In Step (b2), interpolation is performed on the (n+1)-th electric field values to obtain (n+1)-th electric field interpolation values respectively corresponding to the (n+1)-th interpolation points. In Step (b3), a n-th different value is obtained according to the (n+1)-th electric field values, the (n+1)-th electric field interpolation values, the n-th electric field values and the n-th electric field interpolation values. In Step (b4), the second operation process determines whether the n-th different value is less than the threshold value. If the answer is yes, the (n+1)-th electric field values and the (n+1)-th electric field interpolation values are used as the electric filed convergence values. If the answer is no, 1 is added to n and the Step (b) is repeatedly performed.

The initial different value Dᵢ is expressed by a formula:

$${D}_{i} = \frac{\sqrt{{\sum }_{x} {\sum }_{y} {\vert {P}_{n} ( x , y ) - {P}_{0} ( x , y ) \vert}^{2}}}{{\sum }_{x} {\sum }_{y} {P}_{0} ( x , y )} ,$$

and wherein x and y are respectively horizontal and vertical coordinates of the measurement block, and Pₙ(x,y) comprises the n-th electric field values and the n-th electric field interpolation values at the coordinates (x,y), and P₀(x,y) comprises the initial electric field values and the initial electric field interpolation values at the coordinates (x,y).

The n-th different value Dₙ is expressed by a formula:

$${D}_{n} = \frac{\sqrt{{\sum }_{x} {\sum }_{y} {\vert {P}_{n + 1} ( x , y ) - {P}_{n} ( x , y ) \vert}^{2}}}{{\sum }_{x} {\sum }_{y} {P}_{n} ( x , y )} ,$$

and wherein x and y are respectively horizontal and vertical coordinates of the measurement block, and Pₙ(x,y) comprises the n-th electric field values and the n-th electric field interpolation values at the coordinates (x,y), and Pₙ₊₁(x,y) comprises the (n+1)-th electric field values and the (n+1)-th electric field interpolation values at the coordinates (x,y).

The n-th subblocks have identical areas, and the (n+1)-th subblocks have identical areas. The n-th electric field interpolation values and the (n+1)-th electric field interpolation values are respectively obtained by performing triangular interpolation or rectangular interpolation on the n-th electric field values and the (n+1)-th electric field values. The n-th subblock and the (n+1)-th subblock are triangular blocks, rectangular blocks or quadrilateral blocks. The initial electric field interpolation values are obtained by performing triangular interpolation or rectangular interpolation on the initial electric field values.

The present invention also provides a near-field antenna measurement system, which comprises a positioner, an electric field measurement device, a processing device and a display. The electric field measurement device is arranged on the positioner and connected with an antenna under test, and a position of the electric field measurement device corresponds to a position of a measurement block of the antenna under test. For example, the measurement block is a plane. The processing device is connected with the positioner and the electric field measurement device, moves the electric field measurement device to a plurality of initial measurement points at a boundary of the measurement block through the positioner, uses the electric field measurement device to measure initial electric field values of an antenna signal emitted by the antenna under test at the initial measurement points, and chooses a plurality of initial interpolation points different from the initial measurement points on the measurement block. A distance between each initial interpolation point and either the initial interpolation point or the initial measurement point neighboring thereto is less than a half of a wavelength of the antenna signal. The processing device performs interpolation on the initial electric field values to obtain initial electric field interpolation values respectively corresponding to the initial interpolation points. The processing device processes the initial electric field values and the initial electric field interpolation values to obtain electric filed convergence values of the antenna signal at the initial measurement points and the initial interpolation points. The display is connected with the processing device. The processing device uses a near-field to far-field conversion algorithm to convert the electric filed convergence values into a far-field pattern of the antenna under test and uses the display to display the far-field pattern.

The processing device divides the measurement block into a plurality of n-th subblocks along paths formed by the initial measurement point and the initial interpolation point, and n is a natural number. The processing device sequentially chooses each n-th subblock to perform an operation process until the operation processes of the n-th subblocks end. In the operation process, the processing device chooses a plurality of n-th measurement points at a boundary of the n-th subblock, and chooses a plurality of n-th interpolation points on the n-th subblock, and positions of the n-th measurement points and the n-th interpolation points are identical to those of the initial measurement points and the initial interpolation points. The processing device moves the electric field measurement device to the n-th measurement points through the positioner, uses the electric field measurement device to measure n-th electric field values of the antenna signal at the n-th measurement points, performs interpolation on the n-th electric field values to obtain n-th electric field interpolation values respectively corresponding to the n-th interpolation points, obtains an initial different value according to the n-th electric field values, the n-th electric field interpolation values, the initial electric field values and the initial electric field interpolation values, and uses the n-th electric field values and the n-th electric field interpolation values as the electric filed convergence values and ends the operation process when the initial different value is less than a threshold value. When the initial different value is not less than the threshold value, the n endlessly increases until the electric filed convergence values are obtained.

The initial different value Dᵢ is expressed by a formula:

$${D}_{i} = \frac{\sqrt{{\sum }_{x} {\sum }_{y} {\vert {P}_{n} ( x , y ) - {P}_{0} ( x , y ) \vert}^{2}}}{{\sum }_{x} {\sum }_{y} {P}_{0} ( x , y )} ,$$

and wherein x and y are respectively horizontal and vertical coordinates of the measurement block, and Pₙ(x,y) comprises the n-th electric field values and the n-th electric field interpolation values at the coordinates (x,y), and P₀(x,y) comprises the initial electric field values and the initial electric field interpolation values at the coordinates (x,y).

The n-th subblocks have identical areas. The n-th electric field interpolation values are obtained by performing triangular interpolation or rectangular interpolation on the n-th electric field values. The n-th subblock are triangular blocks, rectangular blocks or quadrilateral blocks. The initial electric field interpolation values are obtained by performing triangular interpolation or rectangular interpolation on the initial electric field values.

The positioner is a two-dimension planar positioner. The electric field measurement device further comprises a vector network analyzer and a receiving antenna. The vector network analyzer is connected with the antenna under test and the processing device to receive the emitted antenna signal. The receiving antenna is connected with the vector network analyzer and arranged on the positioner. A position of the receiving antenna corresponds to that of the measurement block. The processing device moves the receiving antenna to the initial measurement points through the positioner. The receiving antenna receives the antenna signal at the initial measurement points and transmits it to the vector network analyzer. The vector network analyzer uses the emitted antenna signal and the received antenna signal corresponding to the initial measurement points, so as to obtain forward transmission coefficients. The processing device uses the forward transmission coefficients to obtain the initial electric field values.

Below, the embodiments are described in detail in cooperation with the drawings to make easily understood the technical contents, characteristics and accomplishments of the present invention.

### BRIEF DESCRIPTION OF THE DRAWINGS

FIG. 1 is a diagram schematically showing a planar near-field antenna measurement system in the conventional technology;

FIG. 2 is a diagram schematically showing the sampling theorem in the conventional technology;

FIG. 3 is a diagram schematically showing a measurement plane divided into ring regions in the conventional technology;

FIG. 4 is a diagram schematically showing a measurement block and measurement points and interpolation points thereon according to an embodiment of the present invention;

FIG. 5 is a diagram schematically showing a near-field antenna measurement system according to an embodiment of the present invention;

FIG. 6 is a flowchart showing a near-field antenna measurement method according to an embodiment of the present invention;

FIG. 7 is a flowchart showing a first operation process according to an embodiment of the present invention;

FIG. 8 is a flowchart showing a second operation process according to an embodiment of the present invention;

FIGS. 9 (a)-9(c) are diagrams schematically showing the steps of dividing the measurement block according to an embodiment of the present invention;

FIG. 10 is a diagram schematically showing a plane using rectangular interpolation of the present invention;

FIG. 11 is a diagram schematically showing a plane using triangular interpolation for three points of the present invention; and

FIG. 12 is a diagram schematically showing a plane using triangular interpolation for six points of the present invention.

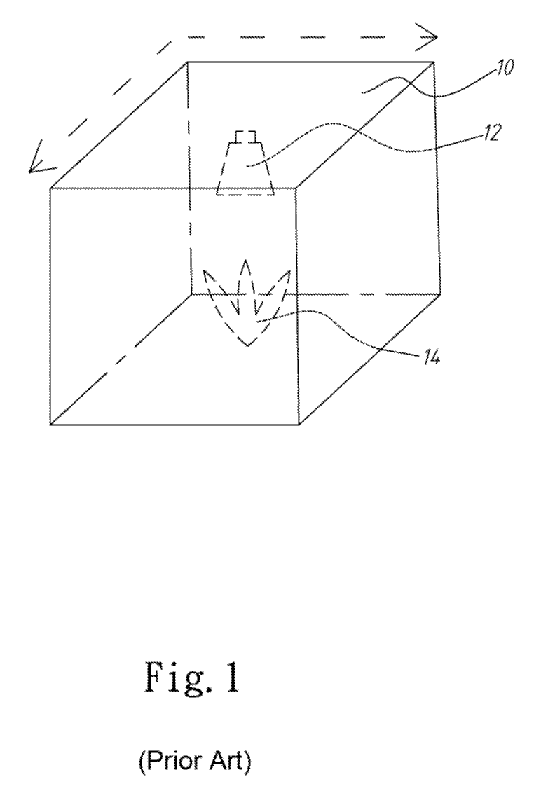

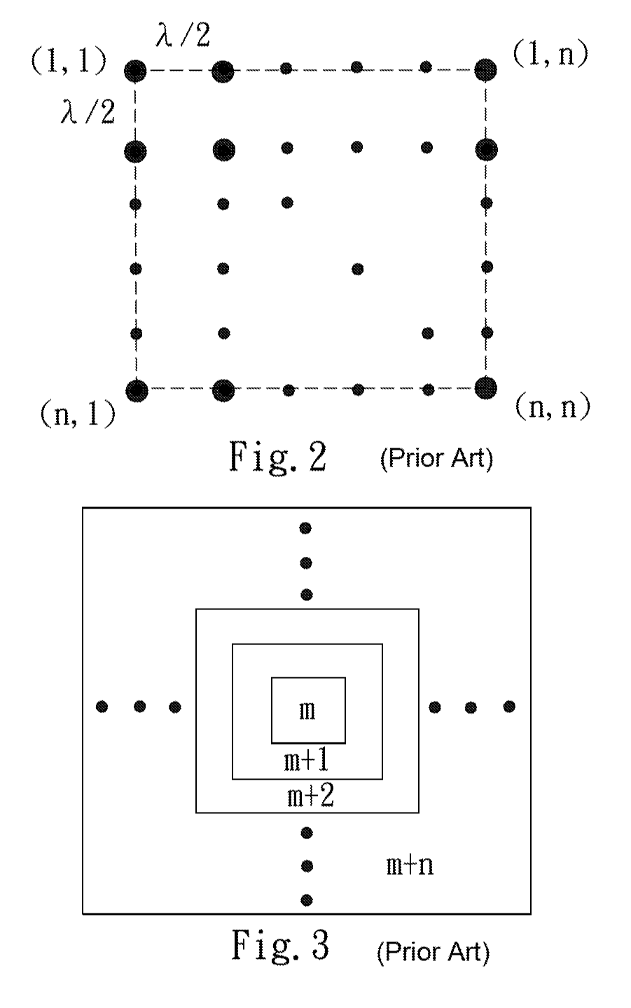

### DETAILED DESCRIPTION OF THE INVENTION

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

In order to solve the problem with time-consuming measurement, the present invention breaks through the conventional technology which complies with the sampling theorem to recover the precise far-field pattern, and reduces the amount of the measured points without changing the pattern, thereby saving time. In order to achieve the purpose, the present invention can determine whether an electric field of a measurement block seriously varies. When the electric field of a region of the measurement block more seriously varies, more electric field values of the region are measured. When the electric field of a region of the measurement block less seriously varies, less electric field values of the region are measured. For example, when the electric field of a position on the measurement block corresponding to a main beam of an antenna pattern seriously varies, more electric field values of the position are measured. On the contrary, when the electric field of a position on the measurement block not corresponding to the main beam of the antenna pattern less seriously varies, less electric field values of the position are measured to save measurement time. The present invention reduces the amount of the measured points as much as possible without changing the pattern, thereby saving time.

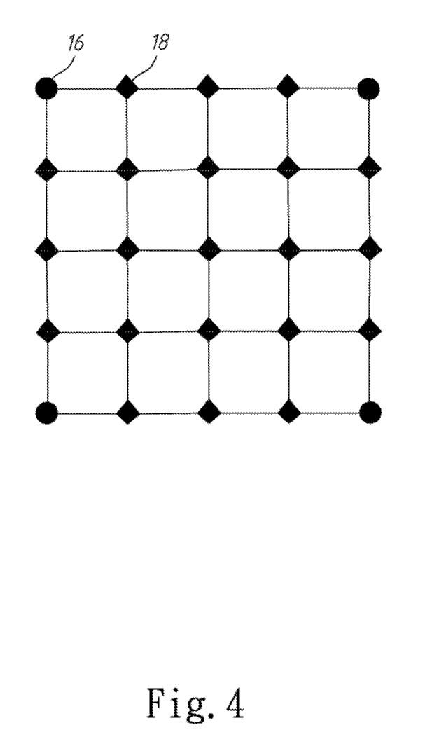

Refer to FIG. 4. The present invention determines whether the measurement data and interpolation data on a measurement block formed by neighboring four points precisely represent the near-field data measured by the sampling theorem. If the answer is yes, too much interpolation data on the measurement block needn't to be measured. In FIG. 4, a circle denotes a measurement point 16, and a diamond denotes an interpolation point 18. The total amount of points on the measurement block is identical to the amount of measurement points for the sampling theorem. Firstly, electric field values at the measurement points 16 are measured. Then, interpolation is used to figure out electric field values at the interpolation points 18. In this way, the measurement data and interpolation data are compared with the interpolation data last time. If they are very close, they are viewed as identical data. Thus, the electric field values at the four measurement points 16 and the twenty-one interpolation points 18 represent the twenty-five electric field values measured by the sampling theorem. In other words, the present invention can save the time of measuring twenty-one electric field values.

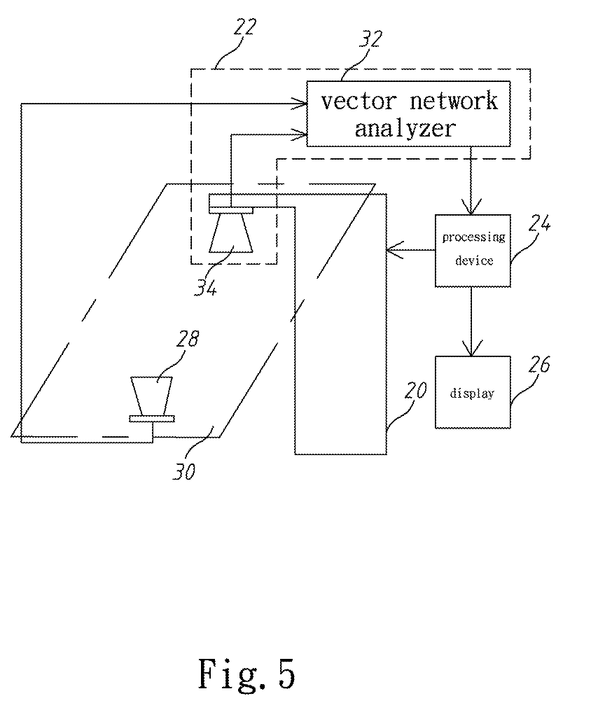

Refer to FIG. 5. The near-field antenna measurement system of the present invention comprises a positioner 20, an electric field measurement device 22, a processing device 24 and a display 26. In the embodiment, the positioner 20 is exemplified by a two-dimensional planar positioner. The electric field measurement device 22 is arranged on the positioner 20 and connected with an antenna under test 28, and a position of the electric field measurement device 22 corresponds to a position of a measurement block 30 of the antenna under test 28. For example, the measurement block 30 is a plane. The processing device 24 is connected with the positioner 20 and the electric field measurement device 22, moves the electric field measurement device 22 to a plurality of initial measurement points at a boundary of the measurement block 30 through the positioner 20, uses the electric field measurement device 22 to measure initial electric field values of an antenna signal emitted by the antenna under test 28 at the initial measurement points, and chooses a plurality of initial interpolation points different from the initial measurement points on the measurement block 30. A distance between each initial interpolation point and either the initial interpolation point or the initial measurement point neighboring thereto is less than a half of a wavelength of the antenna signal, so as to comply with the sampling theorem. The processing device 24 performs interpolation on the initial electric field values to obtain initial electric field interpolation values respectively corresponding to the initial interpolation points. The initial electric field interpolation values are obtained by performing triangular interpolation or rectangular interpolation on the initial electric field values. The processing device 24 processes the initial electric field values and the initial electric field interpolation values to obtain electric filed convergence values of the antenna signal at the initial measurement points and the initial interpolation points. The display 26 is connected with the processing device 24. The processing device 24 uses a near-field to far-field conversion algorithm to convert the electric filed convergence values into a far-field pattern of the antenna under test 28 and uses the display 26 to display the far-field pattern.

The electric field measurement device 22 further comprises a vector network analyzer 32 and a receiving antenna 34. The vector network analyzer 32 is connected with the antenna under test 28 and the processing device 24 to receive the emitted antenna signal. The receiving antenna 34 is connected with the vector network analyzer 32 and arranged on the positioner 20. A position of the receiving antenna 34 corresponds to that of the measurement block 30. The processing device 24 moves the receiving antenna 34 to the initial measurement points through the positioner 20. The receiving antenna 34 receives the antenna signal at the initial measurement points and transmits it to the vector network analyzer 32. The vector network analyzer 32 uses the emitted antenna signal and the received antenna signal corresponding to the initial measurement points, so as to obtain forward transmission coefficients. The processing device 24 uses the forward transmission coefficients to obtain the initial electric field values.

The processing device 24 divides the measurement block 30 into a plurality of n-th subblocks along paths formed by the initial measurement point and the initial interpolation point, and n is a natural number. The n-th subblocks have identical areas. The n-th subblocks are triangular blocks, rectangular blocks or quadrilateral blocks. The processing device 24 sequentially chooses each n-th subblock to perform an operation process until the operation processes of the n-th subblocks end. In the operation process, the processing device 24 chooses a plurality of n-th measurement points at a boundary of the n-th subblock, and chooses a plurality of n-th interpolation points on the n-th subblock, and positions of the n-th measurement points and the n-th interpolation points are identical to those of the initial measurement points and the initial interpolation points. The processing device 24 moves the receiving antenna 34 to the n-th measurement points through the positioner 20, uses the receiving antenna 34 to receive the antenna signal at the n-th measurement points, and transmits it to the vector network analyzer 32. The vector network analyzer 32 uses the emitted antenna signal and the received antenna signal corresponding to the n-th measurement points, so as to obtain n-th forward transmission coefficients. The processing device 24 uses the n-th forward transmission coefficients to obtain the n-th electric field values of the antenna signal. The processing device 24 performs triangular interpolation or rectangular interpolation on the n-th electric field values to obtain n-th electric field interpolation values respectively corresponding to the n-th interpolation points, obtains an initial different value according to the n-th electric field values, the n-th electric field interpolation values, the initial electric field values and the initial electric field interpolation values, and uses the n-th electric field values and the n-th electric field interpolation values as the electric filed convergence values and ends the operation process when the initial different value is less than a threshold value. Besides, when the initial different value is not less than the threshold value, the n endlessly increases until the electric filed convergence values are obtained. The initial different value Dᵢ is expressed by a formula (1):

$${D}_{i} = \frac{\sqrt{{\sum }_{x} {\sum }_{y} {\vert {P}_{n} ( x , y ) - {P}_{0} ( x , y ) \vert}^{2}}}{{\sum }_{x} {\sum }_{y} {P}_{0} ( x , y )} \qquad ( 1 )$$

For formula (1), x and y are respectively horizontal and vertical coordinates of the measurement block, and Pₙ(x,y) comprises the n-th electric field values and the n-th electric field interpolation values at the coordinates (x,y), and P₀(x,y) comprises the initial electric field values and the initial electric field interpolation values at the coordinates (x,y).

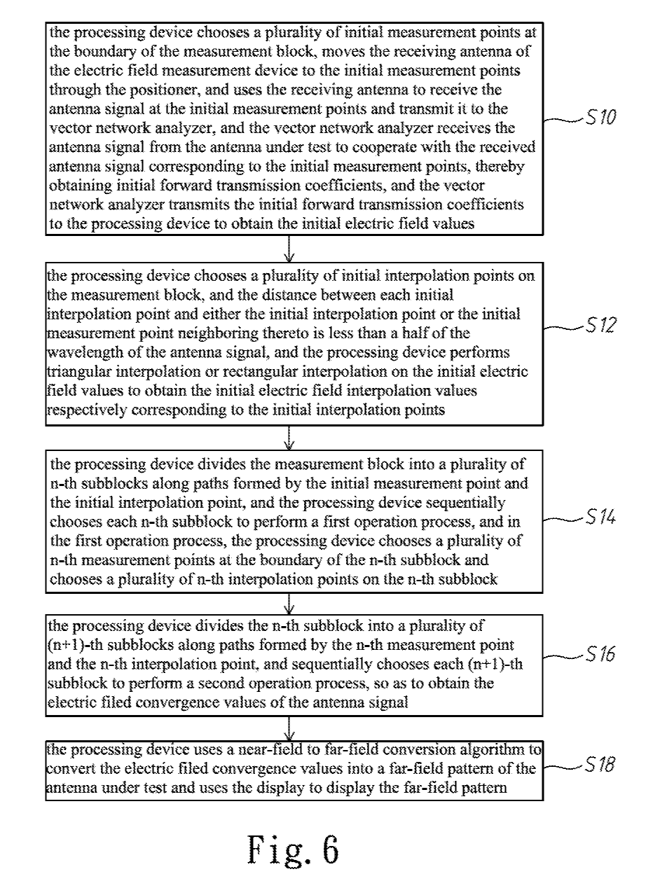

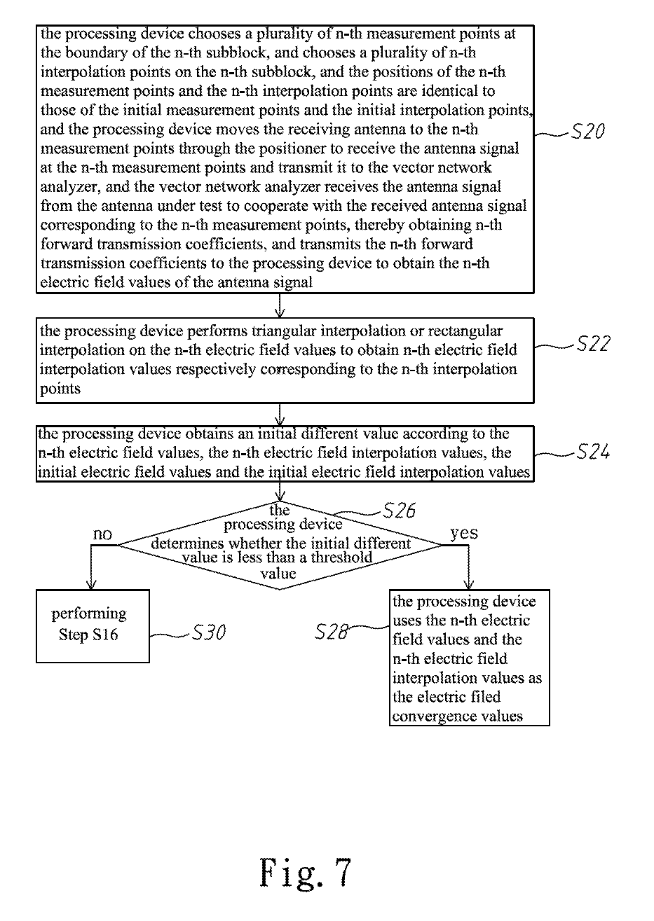

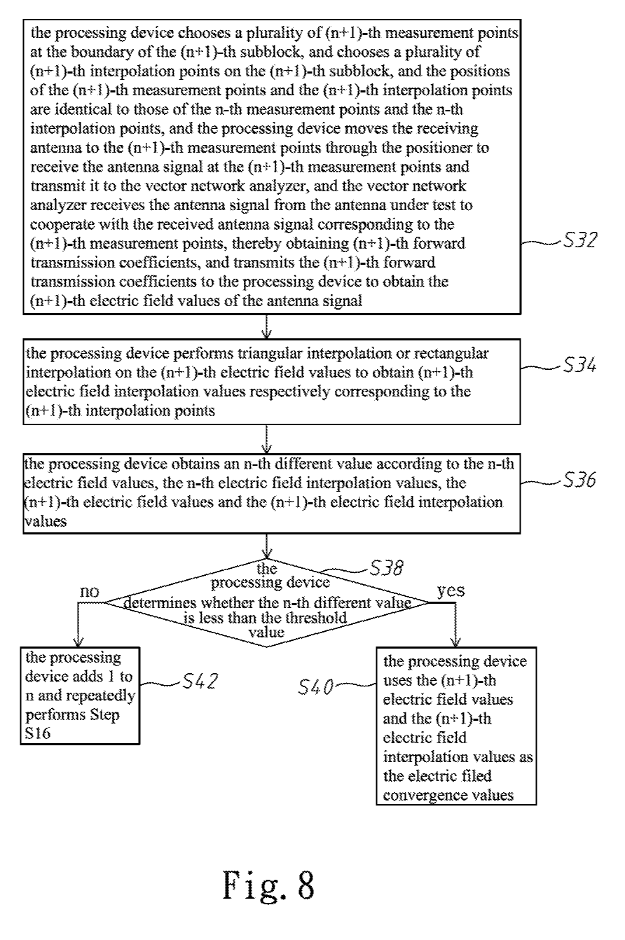

The near-field antenna measurement method of the present invention is introduced below. Refer to FIG. 5, FIG. 6, FIG. 7 and FIG. 8. The near-field antenna measurement method of the present invention chooses the measurement block 30 corresponding to the antenna under test 28 and measures the antenna signal emitted by the antenna under test 28 on the measurement block 30. Firstly, in Step S10, the processing device 24 chooses a plurality of initial measurement points at the boundary of the measurement block 30, moves the receiving antenna 34 of the electric field measurement device 22 to the initial measurement points through the positioner 20, and uses the receiving antenna 34 to receive the antenna signal at the initial measurement points and transmit it to the vector network analyzer 32. The vector network analyzer 32 receives the antenna signal from the antenna under test 28 to cooperate with the received antenna signal corresponding to the initial measurement points, thereby obtaining initial forward transmission coefficients. The vector network analyzer 32 transmits the initial forward transmission coefficients to the processing device 24 to obtain the initial electric field values. Then, in Step S12, the processing device 24 chooses a plurality of initial interpolation points on the measurement block 30. The distance between each initial interpolation point and either the initial interpolation point or the initial measurement point neighboring thereto is less than a half of the wavelength of the antenna signal. The processing device 24 performs triangular interpolation or rectangular interpolation on the initial electric field values to obtain the initial electric field interpolation values respectively corresponding to the initial interpolation points. Then, in Step S14, the processing device 24 divides the measurement block 30 into a plurality of n-th subblocks along paths formed by the initial measurement point and the initial interpolation point, and n is a natural number, and the processing device 24 sequentially chooses each n-th subblock to perform a first operation process. In the first operation process, the processing device 24 chooses a plurality of n-th measurement points at the boundary of the n-th subblock and chooses a plurality of n-th interpolation points on the n-th subblock. For example, the n-th subblocks have identical areas and the n-th subblocks are triangular blocks, rectangular blocks or quadrilateral blocks. After Step S14, Step S16 is performed. In Step S16, the processing device 24 divides the n-th subblock into a plurality of (n+1)-th subblocks along paths formed by the n-th measurement point and the n-th interpolation point, and sequentially chooses each (n+1)-th subblock to perform a second operation process, so as to fast obtain the precise electric filed convergence values of the antenna signal and overcome the time-consuming problem in measurement. For example, the (n+1)-th subblocks have identical areas and the (n+1)-th subblocks are triangular blocks, rectangular blocks or quadrilateral blocks. Finally, in Step S18, the processing device 24 uses a near-field to far-field conversion algorithm to convert the electric filed convergence values into a far-field pattern of the antenna under test 28 and uses the display 26 to display the far-field pattern.

The first operation process is introduced below. Firstly, in Step S20, the processing device 24 chooses a plurality of n-th measurement points at the boundary of the n-th subblock, and chooses a plurality of n-th interpolation points on the n-th subblock, and the positions of the n-th measurement points and the n-th interpolation points are identical to those of the initial measurement points and the initial interpolation points. The processing device 24 moves the receiving antenna 34 to the n-th measurement points through the positioner 20 to receive the antenna signal at the n-th measurement points and transmit it to the vector network analyzer 32. The vector network analyzer 32 receives the antenna signal from the antenna under test 28 to cooperate with the received antenna signal corresponding to the n-th measurement points, thereby obtaining n-th forward transmission coefficients, and transmits the n-th forward transmission coefficients to the processing device 24 to obtain the n-th electric field values of the antenna signal. Then, in Step S22, the processing device 24 performs triangular interpolation or rectangular interpolation on the n-th electric field values to obtain n-th electric field interpolation values respectively corresponding to the n-th interpolation points. Then, in Step S24, the processing device 24 obtains an initial different value according to the n-th electric field values, the n-th electric field interpolation values, the initial electric field values and the initial electric field interpolation values, wherein the initial different value is obtained from formula (1). Finally, in Step S26, the processing device 24 determines whether the initial different value is less than a threshold value. If the answer is yes, the processing device 24 uses the n-th electric field values and the n-th electric field interpolation values as the electric filed convergence values, as shown in Step S28. If the answer is no, Step S16 is performed, as shown in Step 30.

The second operation process is introduced below. Firstly, in Step S32, the processing device 24 chooses a plurality of (n+1)-th measurement points at the boundary of the (n+1)-th subblock, and chooses a plurality of (n+1)-th interpolation points on the (n+1)-th subblock, and the positions of the (n+1)-th measurement points and the (n+1)-th interpolation points are identical to those of the n-th measurement points and the n-th interpolation points. The processing device 24 moves the receiving antenna 34 to the (n+1)-th measurement points through the positioner 20 to receive the antenna signal at the (n+1)-th measurement points and transmit it to the vector network analyzer 32. The vector network analyzer 32 receives the antenna signal from the antenna under test 28 to cooperate with the received antenna signal corresponding to the (n+1)-th measurement points, thereby obtaining (n+1)-th forward transmission coefficients, and transmits the (n+1)-th forward transmission coefficients to the processing device 24 to obtain the (n+1)-th electric field values of the antenna signal. Then, in Step S34, the processing device 24 performs triangular interpolation or rectangular interpolation on the (n+1)-th electric field values to obtain (n+1)-th electric field interpolation values respectively corresponding to the (n+1)-th interpolation points. Then, in Step S36, the processing device 24 obtains an n-th different value according to the n-th electric field values, the n-th electric field interpolation values, the (n+1)-th electric field values and the (n+1)-th electric field interpolation values, wherein the n-th different value is obtained from formula (2). Finally, in Step S38, the processing device 24 determines whether the n-th different value is less than the threshold value. If the answer is yes, the processing device 24 uses the (n+1)-th electric field values and the (n+1)-th electric field interpolation values as the electric filed convergence values, as shown in Step S40. If the answer is no, the processing device 24 adds 1 to n and repeatedly performs Step S16, as shown in Step 42.

$${D}_{n} = \frac{\sqrt{{\sum }_{x} {\sum }_{y} {\vert {P}_{n + 1} ( x , y ) - {P}_{n} ( x , y ) \vert}^{2}}}{{\sum }_{x} {\sum }_{y} {P}_{n} ( x , y )} \qquad ( 2 )$$

For formula (2), x and y are respectively horizontal and vertical coordinates of the measurement block, and Pₙ(x,y) comprises the n-th electric field values and the n-th electric field interpolation values at the coordinates (x,y), and Pₙ₊₁(x,y) comprises the (n+1)-th electric field values and the (n+1)-th electric field interpolation values at the coordinates (x,y).

Step S14 and Step S16 are replaced with a step of the processing device 24 processing the initial electric field values and the initial electric field interpolation values to fast obtain the electric filed convergence values of the antenna signal at the initial measurement points and the initial interpolation points. Step S18 is also omitted whereby the present invention fast obtains the electric filed convergence values of the antenna signal. Besides, if the initial different value is less than the threshold value in the first operation process of each n-th subblock, Step S16 is omitted to directly perform Step S18.

In addition to using the vector network analyzer 32 and the receiving antenna 34 to measure the electric field values, the present invention also uses the electric field measurement device 22 to measure the electric field values. For example, in Step S10, the processing device 24 chooses a plurality of initial measurement points at the boundary of the measurement block 30, moves the electric field measurement device 22 to the initial measurement points through the positioner 20, and uses the electric field measurement device 22 to measure the initial electric field values of the antenna signal at the initial measurement points. In Step S20, the processing device 24 chooses a plurality of n-th measurement points at the boundary of the n-th subblock, and chooses a plurality of n-th interpolation points on the n-th subblock, and the positions of the n-th measurement points and the n-th interpolation points are identical to those of the initial measurement points and the initial interpolation points, and the processing device 24 moves the electric field measurement device 22 to the n-th measurement points through the positioner 20, and uses the electric field measurement device 22 to measure the n-th electric field values of the antenna signal at the n-th measurement points. In Step S32, the processing device 24 chooses a plurality of (n+1)-th measurement points at the boundary of the (n+1)-th subblock, and chooses a plurality of (n+1)-th interpolation points on the (n+1)-th subblock, and the positions of the (n+1)-th measurement points and the (n+1)-th interpolation points are identical to those of the n-th measurement points and the n-th interpolation points, and the processing device 24 moves the electric field measurement device 22 to the (n+1)-th measurement points through the positioner 20, and uses the electric field measurement device 22 to measure the (n+1)-th electric field values of the antenna signal at the (n+1)-th measurement points.

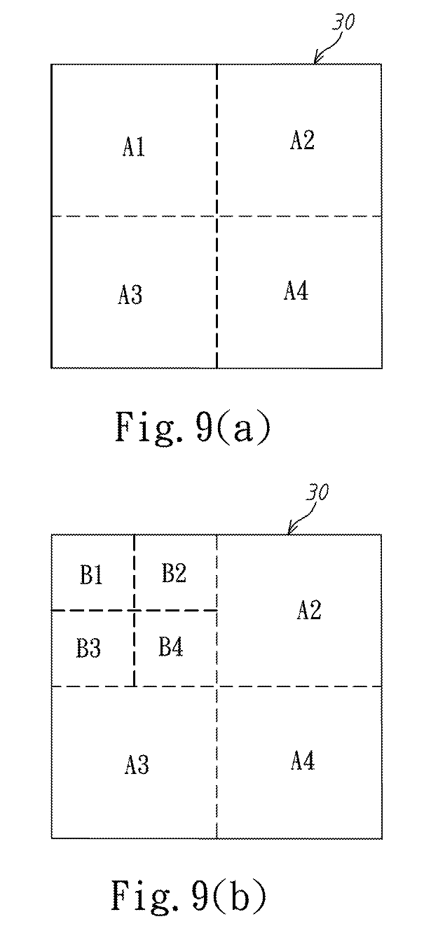

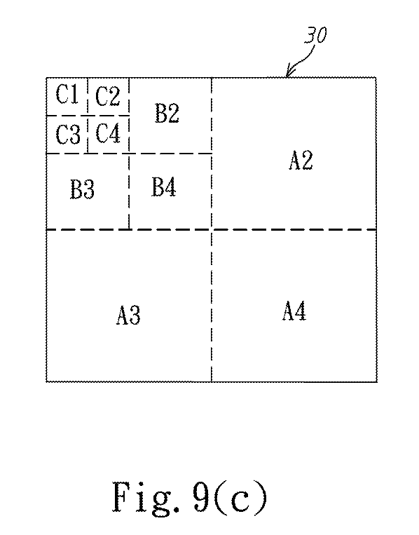

Specifically, the process of the near-field antenna measurement method of the present invention is introduced below. Refer to FIG. 5 and FIGS. 9(a)-9(c). Firstly, the processing device 24 chooses a plurality of initial measurement points at the boundary of the measurement block 30, moves the receiving antenna 34 of the electric field measurement device 22 to the initial measurement points through the positioner 20, and uses the receiving antenna 34 to receive the antenna signal at the initial measurement points and transmit it to the vector network analyzer 32. The vector network analyzer 32 receives the antenna signal from the antenna under test 28 to cooperate with the received antenna signal corresponding to the initial measurement points, thereby obtaining initial forward transmission coefficients. The vector network analyzer 32 transmits the initial forward transmission coefficients to the processing device 24 to obtain the initial electric field values. Then, the processing device 24 chooses a plurality of initial interpolation points on the measurement block 30. The distance between each initial interpolation point and either the initial interpolation point or the initial measurement point neighboring thereto is less than a half of the wavelength of the antenna signal. The processing device 24 performs triangular interpolation or rectangular interpolation on the initial electric field values to obtain the initial electric field interpolation values respectively corresponding to the initial interpolation points. Then, the processing device 24 divides the measurement block 30 into a plurality of first subblocks A1, A2, A3 and A4 along paths formed by the initial measurement point and the initial interpolation point, and sequentially chooses each first subblock A1, A2, A3 and A4 to perform a first operation process.

In the first operation process, the processing device 24 firstly chooses a plurality of first measurement points at the boundary of the first subblock A1 and chooses a plurality of first interpolation points on the first subblock A1. The positions of the first measurement points and the first interpolation points are identical to those of the initial measurement points and the initial interpolation points. Then, The processing device 24 moves the receiving antenna 34 to the first measurement points through the positioner 20 to receive the antenna signal at the first measurement points and transmit it to the vector network analyzer 32. The vector network analyzer 32 receives the antenna signal from the antenna under test 28 to cooperate with the received antenna signal corresponding to the first measurement points, thereby obtaining first forward transmission coefficients, and transmits the first forward transmission coefficients to the processing device 24 to obtain the first electric field values of the antenna signal. Then, the processing device 24 performs triangular interpolation or rectangular interpolation on the first electric field values to obtain first electric field interpolation values respectively corresponding to the first interpolation points. Then, the processing device 24 obtains an initial different value according to the first electric field values, the first electric field interpolation values, the initial electric field values and the initial electric field interpolation values, wherein the initial different value is obtained from formula (1), and n equals to 1. Finally, the processing device 24 determines whether the initial different value is less than a threshold value. Since the initial different value is not less than the threshold value, the processing device 24 divides the first subblock A1 into a plurality of second subblocks B1, B2, B3 and B4 along paths formed by the first measurement point and the first interpolation point, and sequentially chooses each second subblock B1, B2, B3 and B4 to perform a second operation process.

In the second operation process, the processing device 24 firstly chooses a plurality of second measurement points at the boundary of the second subblock B1 and chooses a plurality of second interpolation points on the second subblock B1. The positions of the second measurement points and the second interpolation points are identical to those of the first measurement points and the first interpolation points. Then, The processing device 24 moves the receiving antenna 34 to the second measurement points through the positioner 20 to receive the antenna signal at the second measurement points and transmit it to the vector network analyzer 32. The vector network analyzer 32 receives the antenna signal from the antenna under test 28 to cooperate with the received antenna signal corresponding to the second measurement points, thereby obtaining second forward transmission coefficients, and transmits the second forward transmission coefficients to the processing device 24 to obtain the second electric field values of the antenna signal. Then, the processing device 24 performs triangular interpolation or rectangular interpolation on the second electric field values to obtain second electric field interpolation values respectively corresponding to the second interpolation points. Then, the processing device 24 obtains a first different value according to the first electric field values, the first electric field interpolation values, the second electric field values and the second electric field interpolation values, wherein the first different value is obtained from formula (2), and n equals to 1. Finally, the processing device 24 determines whether the first different value is less than the threshold value. Since the first different value is not less than the threshold value, the processing device 24 divides the second subblock B1 into a plurality of third subblocks C1, C2, C3 and C4 along paths formed by the second measurement point and the second interpolation point, and sequentially chooses each third subblock C1, C2, C3 and C4 to perform a second operation process.

In the second operation process, the processing device 24 firstly chooses a plurality of third measurement points at the boundary of the third subblock C1 and chooses a plurality of third interpolation points on the third subblock C1. The positions of the third measurement points and the third interpolation points are identical to those of the second measurement points and the second interpolation points. Then, The processing device 24 moves the receiving antenna 34 to the third measurement points through the positioner 20 to receive the antenna signal at the third measurement points and transmit it to the vector network analyzer 32. The vector network analyzer 32 receives the antenna signal from the antenna under test 28 to cooperate with the received antenna signal corresponding to the third measurement points, thereby obtaining third forward transmission coefficients, and transmits the third forward transmission coefficients to the processing device 24 to obtain the third electric field values of the antenna signal. Then, the processing device 24 performs triangular interpolation or rectangular interpolation on the third electric field values to obtain third electric field interpolation values respectively corresponding to the third interpolation points. Then, the processing device 24 obtains a second different value according to the third electric field values, the third electric field interpolation values, the second electric field values and the second electric field interpolation values, wherein the second different value is obtained from formula (2), and n equals to 2. Finally, the processing device 24 determines whether the second different value is less than the threshold value. Since the second different value is less than the threshold value, the processing device 24 uses the third electric field values and the third electric field interpolation values as the electric field convergence values.

After the second operation process of the third subblock C1, the second operation processes of the third subblocks C2, C3 and C4 are sequentially performed to obtain the electric field convergence values. The second operation processes of the third subblocks C2, C3 and C4 are identical to the second operation process of the third subblock C1. After the second operation processes of the third subblocks C2, C3 and C4, the second operation processes of the third subblocks B2, B3 and B4 are sequentially performed to obtain the electric field convergence values. The second operation processes of the second subblocks B2, B3 and B4 are identical to the second operation process of the second subblock B1. After the second operation processes of the second subblocks B2, B3 and B4, the first operation processes of the first subblocks A2, A3 and A4 are sequentially performed to obtain the electric field convergence values. The first operation processes of the first subblocks A2, A3 and A4 are identical to the second operation process of the first subblock A1.

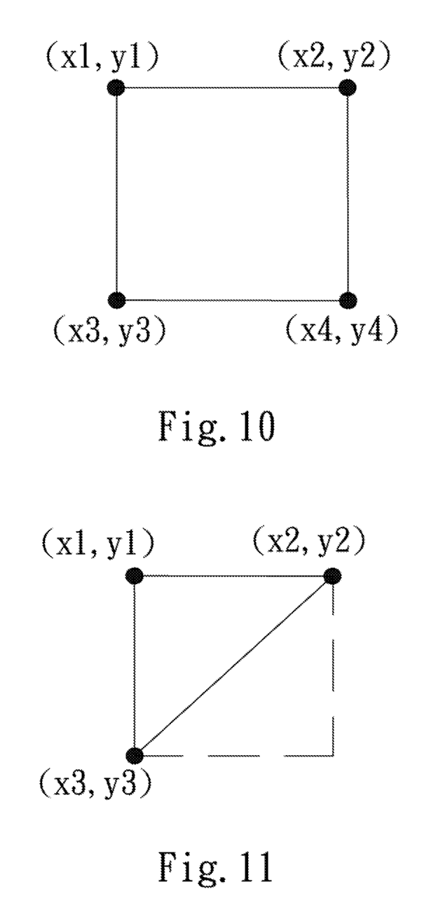

Interpolation of the present invention uses coordinates and electric field values of some points as known items in space and uses the known items to obtain electric field values at an arbitrary position in space. Rectangular interpolation is introduced below. Refer to FIG. 10. Suppose that coordinates of four points in space are (x1,y1), (x2,y2), (x3,y3) and (x4,y4). The four points form a plane and are used as measurement points. The electric field values measured at the four points are P(x1,y1), P(x2,y2), P(x3,y3) and P(x4,y4). The interpolation coefficients α, β, γ and δ are obtained according to formula (3).

$$[ \begin{matrix}P ( x 1 , y 1 ) \\ P ( x 2 , y 2 ) \\ P ( x 3 , y 3 ) \\ P ( x 4 , y 4 )\end{matrix} ] = [ \begin{matrix}1 & x 1 & y 1 & x 1 y 1 \\ 1 & x 2 & y 2 & x 2 y 2 \\ 1 & x 3 & y 3 & x 3 y 3 \\ 1 & x 4 & y 4 & x 4 y 4\end{matrix} ] [ \begin{matrix}α \\ β \\ γ \\ δ\end{matrix} ] \qquad ( 3 )$$

After obtaining the interpolation coefficients α, β, γ and δ, the electric field value P(x,y) at an arbitrary point on the plane is obtained according to formula (4), wherein (x,y) is a coordinate of an arbitrary point on the plane.

P(x,y)=α+βx+γy+δxy (4)

Since an arbitrary polygon is divided into different triangles, a triangle is the smallest unit forming a polygon. As a result, the present invention also uses triangular interpolation. Triangular interpolation further includes triangular interpolation for three points or six points. Triangular interpolation for three points is introduced below. Refer to FIG. 11. Suppose that coordinates of three points in space are (x1,y1), (x2,y2) and (x3,y3). The three points form a triangle plane and are used as measurement points. The electric field values measured at the three points are P(x1,y1), P(x2,y2) and P(x3,y3). The interpolation coefficients α, β and γ are obtained according to formula (5).

$$[ \begin{matrix}P ( x 1 , y 1 ) \\ P ( x 2 , y 2 ) \\ P ( x 3 , y 3 )\end{matrix} ] = [ \begin{matrix}1 & x 1 & y 1 \\ 1 & x 2 & y 2 \\ 1 & x 3 & y 3\end{matrix} ] [ \begin{matrix}α \\ β \\ γ\end{matrix} ] \qquad ( 5 )$$

After obtaining the interpolation coefficients α, β and γ, the electric field value P(x,y) at an arbitrary point on the triangle plane is obtained according to formula (6), wherein (x,y) is a coordinate of an arbitrary point on the triangle plane.

P(x,y)=α+βx+γy (6)

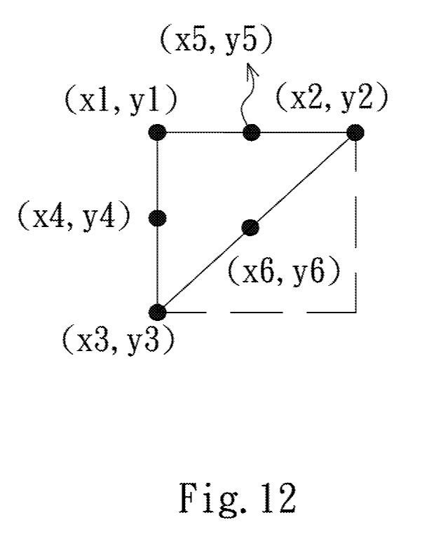

Triangular interpolation for six points is introduced below. Refer to FIG. 12. Triangular interpolation for six points uses three apexes of a triangle plane and a midpoint between the two neighboring apexes. The order of triangular interpolation for six points is higher than triangular interpolation for three points. As a result, the interpolation data calculated by triangular interpolation for six points is more precise than the interpolation data calculated by triangular interpolation for three points. Suppose that coordinates of three points in space are (x1,y1), (x2,y2) and (x3,y3). The three points are used apexes to form a triangle plane, and coordinate of a midpoint between two neighboring apexes is (x4,y4), (x5,y5) or (x6,y6). The apexes and the midpoints are used as measurement points. The electric field values measured at the six points are P(x1,y1), P(x2,y2), P(x3,y3), (x4,y4), (x5,y5) and (x6,y6). The interpolation coefficients α, β, γ, ε and μ are obtained according to formula (7).

$$[ \begin{matrix}P ( x 1 , y 1 ) \\ P ( x 2 , y 2 ) \\ P ( x 3 , y 3 ) \\ P ( x 4 , y 4 ) \\ P ( x 5 , y 5 ) \\ P ( x 6 , y 6 )\end{matrix} ] = [ \begin{matrix}1 & x 1 & y 1 \\ 1 & x 2 & y 2 \\ 1 & x 3 & y 3 \\ 1 & x 4 & y 4 \\ 1 & x 5 & y 5 \\ 1 & x 6 & y 6\end{matrix} ] [ \begin{matrix}α \\ β \\ γ \\ δ \\ ɛ \\ μ\end{matrix} ] \qquad ( 7 )$$

After obtaining the interpolation coefficients α, β, γ, ε and μ, the electric field value P(x,y) at an arbitrary point on the triangle plane is obtained according to formula (8), wherein (x,y) is a coordinate of an arbitrary point on the triangle plane.

P(x,y)=α+βx+γy+δx²+εxy+μy² (8)

In conclusion, the present invention samples the electric field on the measurement block in a rough way, and then performs interpolation on the electric field to obtain interpolation data, and then samples the electric field in a fine way. When the difference between the results sampled in a fine way and the interpolation data is less than a threshold value, the present invention needn't sample the electric field in a finer way. When the difference is larger than the threshold value, the present invention needs to sample the electric field in a finer way. The abovementioned process is repeated until all the differences of the measurement block are less than the threshold value, whereby the precise electric field convergence values are fast obtained to display the precise far-field pattern.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. A near-field antenna measurement method choosing a measurement block corresponding to an antenna under test and measuring an antenna signal emitted by said antenna under test, and said near-field antenna measurement method comprising:
choosing a plurality of initial measurement points at a boundary of said measurement block and measuring initial electric field values of said antenna signal at said initial measurement points;
choosing a plurality of initial interpolation points on said measurement block, and a distance between each said initial interpolation point and either said initial interpolation point or said initial measurement point neighboring thereto is less than a half of a wavelength of said antenna signal, and performing interpolation on said initial electric field values to obtain initial electric field interpolation values respectively corresponding to said initial interpolation points; and
processing said initial electric field values and said initial electric field interpolation values to obtain electric filed convergence values of said antenna signal at said initial measurement points and said initial interpolation points.

2. The near-field antenna measurement method of claim 1, further comprising a step of using a near-field to far-field conversion equation to convert said electric filed convergence values into a far-field pattern of said antenna under test and displaying said far-field pattern.

3. The near-field antenna measurement method of claim 1, wherein said step of processing said initial electric field values and said initial electric field interpolation values to obtain said electric field convergence values further comprises:
Step (a): dividing said measurement block into a plurality of n-th subblocks along paths formed by said initial measurement point and said initial interpolation point, and n is a natural number, and sequentially choosing each said n-th subblock to perform a first operation process, and said first operation process further comprises steps of:
Step (a1): choosing a plurality of n-th measurement points at a boundary of said n-th subblock, and choosing a plurality of n-th interpolation points on said n-th subblock, and positions of said n-th measurement points and said n-th interpolation points are identical to those of said initial measurement points and said initial interpolation points, and measuring n-th electric field values of said antenna signal at said n-th measurement points;
Step (a2): performing interpolation on said n-th electric field values to obtain n-th electric field interpolation values respectively corresponding to said n-th interpolation points;
Step (a3): obtaining an initial different value according to said n-th electric field values, said n-th electric field interpolation values, said initial electric field values and said initial electric field interpolation values; and
Step (a4): determining whether said initial different value is less than a threshold value:
if yes, said n-th electric field values and said n-th electric field interpolation values are used as said electric filed convergence values; and
if no, executing a step of; and
Step (b): dividing said n-th subblock into a plurality of (n+1)-th subblocks along paths formed by said n-th measurement point and said n-th interpolation point, and sequentially choosing each said (n+1)-th subblock to perform a second operation process, and said second operation process further comprises steps of:
Step (b1): choosing a plurality of (n+1)-th measurement points at a boundary of said (n+1)-th subblock, and choosing a plurality of (n+1)-th interpolation points on said (n+1)-th subblock, and positions of said (n+1)-th measurement points and said (n+1)-th interpolation points are identical to those of said n-th measurement points and said n-th interpolation points, and measuring (n+1)-th electric field values of said antenna signal at said (n+1)-th measurement points;
Step (b2): performing interpolation on said (n+1)-th electric field values to obtain (n+1)-th electric field interpolation values respectively corresponding to said (n+1)-th interpolation points;
Step (b3): obtaining a n-th different value according to said (n+1)-th electric field values, said (n+1)-th electric field interpolation values, said n-th electric field values and said n-th electric field interpolation values; and
Step (b4): determining whether said n-th different value is less than said threshold value:
if yes, said (n+1)-th electric field values and said (n+1)-th electric field interpolation values are used as said electric filed convergence values; and
if no, adding 1 to n and repeatedly performing said Step (b).

4. The near-field antenna measurement method of claim 3, wherein said initial different value Dᵢ is expressed by a formula:
$${D}_{i} = \frac{\sqrt{{\sum }_{x} {\sum }_{y} {\vert {P}_{n} ( x , y ) - {P}_{0} ( x , y ) \vert}^{2}}}{{\sum }_{x} {\sum }_{y} {P}_{0} ( x , y )} ,$$
and wherein x and y are respectively horizontal and vertical coordinates of said measurement block, and Pₙ(x,y) comprises said n-th electric field values and said n-th electric field interpolation values at said coordinates (x,y), and P₀(x,y) comprises said initial electric field values and said initial electric field interpolation values at said coordinates (x,y).

5. The near-field antenna measurement method of claim 3, wherein said n-th different value Dₙ is expressed by a formula:
$${D}_{n} = \frac{\sqrt{{\sum }_{x} {\sum }_{y} {\vert {P}_{n + 1} ( x , y ) - {P}_{n} ( x , y ) \vert}^{2}}}{{\sum }_{x} {\sum }_{y} {P}_{n} ( x , y )} ,$$
and wherein x and y are respectively horizontal and vertical coordinates of said measurement block, and Pₙ(x,y) comprises said n-th electric field values and said n-th electric field interpolation values at said coordinates (x,y), and Pₙ₊₁(x,y) comprises said (n+1)-th electric field values and said (n+1)-th electric field interpolation values at said coordinates (x,y).

6. The near-field antenna measurement method of claim 3, wherein said n-th subblocks have identical areas, and said (n+1)-th subblocks have identical areas.

7. The near-field antenna measurement method of claim 3, wherein said n-th electric field interpolation values and said (n+1)-th electric field interpolation values are respectively obtained by performing triangular interpolation or rectangular interpolation on said n-th electric field values and said (n+1)-th electric field values.

8. The near-field antenna measurement method of claim 3, wherein said n-th subblock and said (n+1)-th subblock are triangular blocks, rectangular blocks or quadrilateral blocks.

9. The near-field antenna measurement method of claim 1, wherein said measurement block is a plane.

10. The near-field antenna measurement method of claim 1, wherein said initial electric field interpolation values are obtained by performing triangular interpolation or rectangular interpolation on said initial electric field values.

11. A near-field antenna measurement system comprising:
a positioner;
an electric field measurement device arranged on said positioner, and a position of said electric field measurement device corresponds to a position of a measurement block of an antenna under test; and
a processing device connected with said positioner and said electric field measurement device, moving said electric field measurement device to a plurality of initial measurement points at a boundary of said measurement block through said positioner, using said electric field measurement device to measure initial electric field values of an antenna signal emitted by said antenna under test at said initial measurement points, choosing a plurality of initial interpolation points different from said initial measurement points on said measurement block, and a distance between each said initial interpolation point and either said initial interpolation point or said initial measurement point neighboring thereto is less than a half of a wavelength of said antenna signal, and said processing device performs interpolation on said initial electric field values to obtain initial electric field interpolation values respectively corresponding to said initial interpolation points, and said processing device processes said initial electric field values and said initial electric field interpolation values to obtain electric filed convergence values of said antenna signal at said initial measurement points and said initial interpolation points.

12. The near-field antenna measurement system of claim 11, further comprising a display connected with said processing device, and said processing device uses a near-field to far-field conversion algorithm to convert said electric filed convergence values into a far-field pattern of said antenna under test and uses said display to display said far-field pattern.

13. The near-field antenna measurement system of claim 11, wherein said processing device divides said measurement block into a plurality of n-th subblocks along paths formed by said initial measurement point and said initial interpolation point, and n is a natural number, and said processing device sequentially chooses each said n-th subblock to perform an operation process until said operation processes of said n-th subblocks end; and in said operation process, said processing device chooses a plurality of n-th measurement points at a boundary of said n-th subblock, and chooses a plurality of n-th interpolation points on said n-th subblock, and positions of said n-th measurement points and said n-th interpolation points are identical to those of said initial measurement points and said initial interpolation points, and said processing device moves said electric field measurement device to said n-th measurement points through said positioner, uses said electric field measurement device to measure n-th electric field values of said antenna signal at said n-th measurement points, performs interpolation on said n-th electric field values to obtain n-th electric field interpolation values respectively corresponding to said n-th interpolation points, obtains an initial different value according to said n-th electric field values, said n-th electric field interpolation values, said initial electric field values and said initial electric field interpolation values, and uses said n-th electric field values and said n-th electric field interpolation values as said electric filed convergence values and ends said operation process when said initial different value is less than a threshold value.

14. The near-field antenna measurement system of claim 13, wherein said n endlessly increases until said electric filed convergence values are obtained.

15. The near-field antenna measurement system of claim 13, wherein said initial different value Dᵢ is expressed by a formula:
$${D}_{i} = \frac{\sqrt{{\sum }_{x} {\sum }_{y} {\vert {P}_{n} ( x , y ) - {P}_{0} ( x , y ) \vert}^{2}}}{{\sum }_{x} {\sum }_{y} {P}_{0} ( x , y )} ,$$
and wherein x and y are respectively horizontal and vertical coordinates of said measurement block, and Pₙ(x,y) comprises said n-th electric field values and said n-th electric field interpolation values at said coordinates (x,y), and P₀(x,y) comprises said initial electric field values and said initial electric field interpolation values at said coordinates (x,y).

16. The near-field antenna measurement system of claim 13, wherein said n-th subblocks have identical areas.

17. The near-field antenna measurement system of claim 13, wherein said n-th electric field interpolation values are obtained by performing triangular interpolation or rectangular interpolation on said n-th electric field values.

18. The near-field antenna measurement system of claim 13, wherein said n-th subblock are triangular blocks, rectangular blocks or quadrilateral blocks.

19. The near-field antenna measurement system of claim 11, wherein measurement block is a plane.

20. The near-field antenna measurement system of claim 11, wherein said initial electric field interpolation values are obtained by performing triangular interpolation or rectangular interpolation on said initial electric field values.

21. The near-field antenna measurement system of claim 11, wherein said positioner is a two-dimension planar positioner.

22. The near-field antenna measurement system of claim 11, wherein said electric field measurement device further comprises:
a vector network analyzer connected with said antenna under test and said processing device to receive emitted said antenna signal; and
a receiving antenna connected with said vector network analyzer, arranged on said positioner, a position of said receiving antenna corresponds to that of said measurement block, and said processing device moves said receiving antenna to said initial measurement points through said positioner, and said receiving antenna receives said antenna signal at said initial measurement points and transmits it to said vector network analyzer, and said vector network analyzer uses said emitted said antenna signal and received said antenna signal corresponding to said initial measurement points, so as to obtain forward transmission coefficients, and said processing device uses said forward transmission coefficients to obtain said initial electric field values.
